(19) United States
(12) Patent Application Publication
(10) Pub. No.: US 2020/0199735 A1
(43) Pub. Date: Jun. 25, 2020

(54) MICROMECHANIC STRUCTURE AND METHOD FOR MAKING THE MICROMECHANIC STRUCTURE

(71) Applicant: Spectrolytic Ltd., Edinburgh (GB)

(72) Inventor: Benjamin Wiesent, Wernberg-Koeblitz (DE)

(21) Appl. No.: 16/805,628

(22) Filed: Feb. 28, 2020

Related U.S. Application Data
(63) Continuation of application No. PCT/EP2018/000415, filed on Aug. 24, 2018.

(30) Foreign Application Priority Data
Aug. 28, 2017 (DE) 10 2017 008 146.8
May 26, 2018 (DE) 10 2018 004 257.0

(51) Int. Cl. C23C 14/08; C23C 14/34; G01J 5/02; G01J 5/04; G01J 5/34; H01L 37/02; H01L 41/09; H01L 41/187; H01L 41/316

(52) U.S. Cl. CPC C23C 14/088; C23C 14/3464; G01J 5/024; G01J 5/046; H01L 41/316; H01L 37/025; H01L 41/09; H01L 41/1876; G01J 5/34

(57) ABSTRACT

A micromechanic structure includes a substrate, an adhesion layer arranged on the substrate, a first metal layer arranged on the adhesion layer, a ferroelectric layer arranged on the first metal layer and including lead zirconate titanate, and a second metal layer arranged on the ferroelectric layer, wherein the lead concentration of the ferroelectric layer decreases in a stepped manner with increasing distance from the first metal layer such that the ferroelectric layer includes a plurality of partial layers in which the lead concentration is respectively uniform.

### CROSS REFERENCE TO RELATED APPLICATIONS

This application is a continuation application of international patent application PCT/EP2018/000415, filed Aug. 24, 2018, designating the United States and claiming priority to German Application Nos. 10 2017 008 146.8, filed Aug. 28, 2017 and 10 2018 004 257.0, filed on May 26, 2018, and the entire contents of these applications are incorporated herein by reference.

### TECHNICAL FIELD

The disclosure relates to a micromechanic structure and a method for making the micromechanic structure.

### BACKGROUND

Ferroelectric layers can be applied in different applications and the dielectric, piezoelectric, and/or pyroelectric properties of the ferroelectric layers can thereby be used. Typical applications for the ferroelectric layers are condenser, actuators, storage media, or pyroelectric detectors.

The ferroelectric layers are conventionally made by a gas phase deposition process, since the gas phase deposition process has a high degree of reproducibility. For example, a chemical vapour deposition (CVD) or a physical vapour deposition (PVD) method are possible for the gas phase deposition process. For example, a vapour deposition process or sputtering are possible for the PVD process.

Characteristic parameters for the ferroelectric layer are its piezoelectric coefficient or its pyroelectric coefficient. The piezoelectric coefficient describes the conversion efficiency of the ferroelectric layer from electrical energy into mechanical energy and the pyroelectric coefficient describes the conversion efficiency of the ferroelectric layer from electromagnetic radiation energy into electrical energy.

The pyroelectric layer can for example be lead zirconate titanate (PZT). If the lead zirconate titanate is deposited on a silicon wafer by of a PVD process, it can be observed that the thickness and the pyroelectric coefficient of the ferroelectric layer vary along the wafer. As a result, a part of the wafer coated with the PZT may not be suited for a required application, for example because the pyroelectric coefficient is not sufficiently high. As a result, this part of the wafer has to be sorted out as a waste which reduces the yield of the PVD process.

### SUMMARY

It is an object of the disclosure to provide a micromechanic structure and a method for making the micromechanic structure, for which the variation of the pyroelectric coefficient of the ferroelectric layer along the substrates is low.

The micromechanic structure according to the disclosure includes a substrate, an adhesion layer that is deposited on the substrate, a first metal layer that is deposited on the adhesion layer, a ferroelectric layer arranged on the first metal layer and including lead zirconate titanate, and a second metal layer arranged on the ferroelectric layer, wherein the lead concentration of the ferroelectric layer decreases in a stepped manner with increasing distance from the first metal layer such that the ferroelectric layer includes a plurality of partial layers in which the lead concentration is respectively uniform.

It was thereby been unextectedly found that the variation of the pyroelectric coefficient of the ferroelectric layer in the micromechanic structure according to the disclosure is essentially lower as if the lead concentration would be uniform in the complete ferroelectric layer. During the making of the micromechanic structure according to the disclosure, fewer waste or no waste therefore incurs that would have to be sorted out.

It is typical that the thickness of the partial layers is in a range from 100 nm to 900 nm, in particular in a range from 400 nm to 600 nm, in particular 500 nm. The variations of the thickness of the ferroelectric layer and the pyroelectric coefficient are particularly low with these thicknesses.

The thickness of the ferroelectric layer is typically in a range from 200 nm to 5000 nm. The variations of the thickness and the pyroelectric coefficient of the ferroelectric layer are particular low with these thicknesses.

It is typical that the ferroelectric layer has a pyroelectric coefficient higher than 1.5*10⁻⁴ C/(m²K), in particular higher than 2.0*10⁻⁴ C/(m²K).

It is typical that in the ferroelectric layer for the lead concentration c(Pb), the zirconium concentration c(Zr) and the titanium concentration c(Ti), c(Pb)/(c(Zr)+c(Ti)) is in a range from 0.9 to 1.0, and c(Zr)/(c(Zr)+c(Ti)) is in a range from 0.1 to 0.3. With these values, a high pyroelectric coefficient with simultaneous particular low variation of the pyroelectric coefficient is obtained.

The micromechanic structure is typically an infrared light sensor. Alternatively or additionally, the micromechanic structure is an actuator.

In the method according to the disclosure for making the micromechanic structure the ferroelectric layer is arranged by a sputter process, in particular by a confocal sputter process.

It is thereby typical that the lead, the zirconium and the titanium of the lead zirconate titanate are simultaneously deposited from three different sputter targets, wherein each of the sputter targets includes only one of the three elements lead, zirconium, and titanium. By using the three sputter targets, the concentrations of the lead, the zirconium and the titanium can be individually adjusted. In order to form the oxides of the lead zirconate titanate, the atmosphere, in which the sputter process is performed, includes typically oxygen.

It is typical that the lead concentration in the ferroelectric layer decreases in the stepped manner with increasing distance from the first metal layer by lowering only the sputter rate of the lead, in particular by lowering an electrical power that is applied on the sputter target that includes the lead. This is a particularly simple method to change the lead concentration in the ferroelectric layer. The sputter rate is a deposited amount of the respective element per time unit. The electrical power that is thereby applied on the target that includes the lead is typically lowered starting from an electrical start power P_{max,lead} by a value that is from 0.2 W to 2 W per a distance of 100 nm from the first metal layer, the value is in particular 1 W per a distance of 100 nm from the first metal layer.

### BRIEF DESCRIPTION OF THE DRAWINGS

The disclosure will now be described with reference to the drawings wherein:

FIG. 1 shows a cross section through a micromechanic structure, and

FIG. 2 shows a plot of a lead concentration versus an electrical power

### DESCRIPTION OF EXEMPLARY EMBODIMENTS

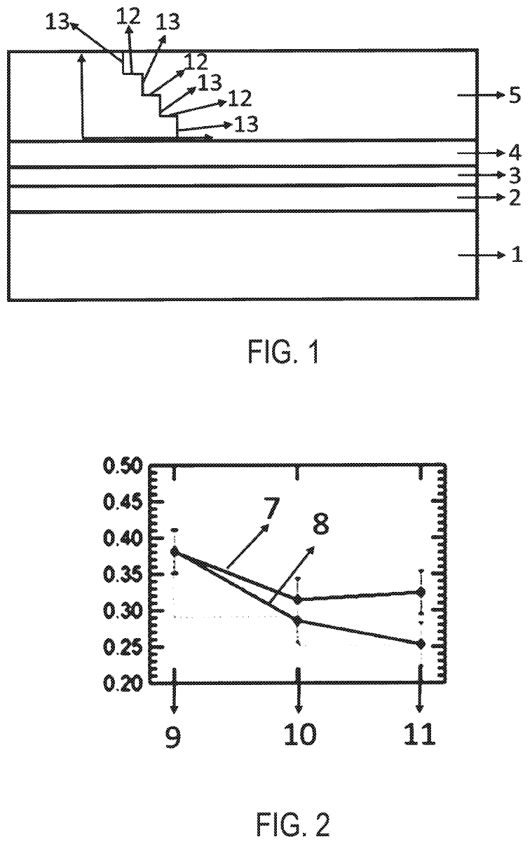

As shown in FIG. 1, the micromechanic structure includes a substrate 1, a carrier membrane 2, an adhesion layer 3, a first metal layer 4, and a ferroelectric layer 5. In addition, the micromechanic structure includes a second metal layer that is not shown. The substrate 1 can for example be a silicon wafer or a quartz wafer.

The carrier membrane 2 is immediately deposited on the substrate 1 and can for example include at least one silicon oxide layer and at least one silicon nitride layer that are arranged alternatingly in the vertical direction as shown in FIG. 1. The thickness of the carrier membrane is in a range from 500 nm to 3000 nm. The micromechanic structure can include a further of the carrier membrane that is immediately deposited on a second side of the substrate 1 that is arranged facing away a first side, on which the carrier membrane is immediately deposited.

The adhesion layer 3 is immediately deposited on the carrier membrane 2 and includes for example titanium oxide and/or aluminium oxide, in particular the adhesion layer 3 may consist substantially of titanium oxide and/or aluminium oxide. The thickness of the adhesion layer 3 is from 2 nm to 50 nm, in particular from 5 nm to 30 nm. The adhesion layer 3 can be deposited by a gas phase deposition process. The adhesion layer causes a good adhesion of the first metal layer 4 on the substrate 1.

The first metal layer 4 is immediately deposited on the adhesion layer 3 and includes an oxidation resistant metal, for example gold and/or platinum. The first metal layer 4 functions as a bottom electrode for the ferroelectric layer 5. The thickness of the first metal layer 4 is from 10 nm to 200 nm. The first metal layer can be deposited by a gas phase deposition process, for example sputtering. During depositing the first metal layer, it is advantageous if the temperature of the substrate 1 does not deviate by more than 100° C. from the temperature of the substrate 1 during depositing the ferroelectric layer 5.

The ferroelectric layer 5 is immediately deposited on the first metal layer 4 and includes lead zirconate titanate, the ferroelectric layer 5 in particular consists substantially of lead zirconate titanate. The lead concentration in the ferroelectric layer 5 decreases in stepped manner with increasing distance from the first metal layer 4, such that the ferroelectric layer 5 includes a plurality of partial layers 13, wherein the lead concentration is uniform in each partial layer 13, respectively. The lead concentrations are different in each of the partial layers 13. A boundary layer 12 is arranged between two immediately adjacent of the partial layers 13, respectively. The boundary layers 12 are arranged parallel to each other and parallel to the first side of the substrate 1. A plot is drawn in FIG. 1, in which the lead concentration is plotted over the horizontal axis and the distance from the first metal layer 4 is plotted over the vertical axis. Lead concentration characteristics 6 are drawn in the plot, wherein the lead concentration characteristics 6 illustrate a stepped decrease of the lead concentration. The thickness of the partial layers 13 is from 100 nm to 900 nm, in particular from 400 nm to 600 nm, in particular 500 nm. All the partial layers 13 can thereby have the same thickness. The thickness of the ferroelectric layer 5 is from 200 nm to 5000 nm. In the ferroelectric layer 5, for the lead concentration c(PB), the zirconium concentration c(Zr), and the titanium concentration c(Ti), c(Pb)/(c(Zr)+c(Ti)) is in a range from 0.9 to 1.0, and c(Zr)/(c(Zr)+c(Ti)) is in a range from 0.1 to 0.3. The unit of the concentrations is for example mol/l. It is thereby: c₁(Pb)/(c₁(Zr)+c₁(Ti))<c₂(Pb)/(c₂(Zr)+c₂(Ti))< . . . <c_{N}(Pb)/(c_{N}(Zr)+c_{N}(Ti)), where N is the number of the partial layers 13, c₁ are the concentrations in the first of the partial layer 13, c₂ are the concentrations in the second of the partial layers 13, and c_{N} are the concentrations in the N-th of the partial layers 13 as well as the index in the concentrations increases with increasing distance from the first metal layer. In addition, it can be: c₁(Zr)/(c₁(Zr)+c₁(Ti))=c₂(Zr)/(c₂(Zr)+c₂(Ti))= . . . =c_{N}(Zr)/(c_{N}(Zr)+c_{N}(Ti)). The ferroelectric layer 5 has a Perovskit structure. The ferroelectric layer has a pyroelectric coefficient higher than 1.5*10⁻⁴ C/(m²K).

The second metal layer is immediately deposited on the ferroelectric layer and includes an oxidation-resistant metal, for example gold and/or platinum. The second metal layer functions as a head electrode for the ferroelectric layer 5. The thickness of the second metal layer is from 10 nm to 200 nm. The second metal layer can be deposited by a gas phase deposition process, for examples sputtering. During depositing the second metal layer, it is advantageous, if the temperature of the substrate 1 does not deviate by more than 100° C. from the temperature of the substrate 1 during depositing the ferroelectric layer 5.

The thicknesses of the carrier membrane 2, the adhesion layer 3, the first metal layer 4, the ferroelectric layer 5, the partial layers 13, and the second metal layer are thereby in FIG. 1 the extensions of the respective layer in vertical direction.

The micromechanic structure can for example be an infrared light sensor and/or an actuator. If the micromechanic structure is the infrared light sensor, it is desirable if the pyroelectric coefficient of the ferroelectric layer 5 is as high as possible. If the micromechanic structure is the actuator, it is desirable that the piezoelectric coefficient of the ferroelectric layer is as high as possible.

The ferroelectric layer 5 is deposited by a sputtering process, in particular by a confocal sputtering process. The lead, the zirconium and the titanium of the lead zirconate titanate are simultaneously deposited from three different sputter targets, wherein each of the sputter targets includes only one of the three elements lead, zirconium, and titanium. During depositing of the ferroelectric layer, the substrate 1 has a temperature from 420° C. to 700° C. The sputter rates of the lead, the zirconium, and the titanium are adjusted by applying a respective electrical power on the three sputter targets. An electrical potential between each of the sputter targets and the substrate 1 is generated during sputtering, such that ions dissolved out of the sputter targets are transported in direction to the substrate 1. The electrical power thereby relates to an electrical current flowing from each of the sputter targets to the substrate. The lead concentration c(Pb), the zirconium concentration c(Zr), and the titanium concentration c(Ti) present in the ferroelectric layer 5 are adjusted by the electrical power applied to the corresponding sputter target.

It is achieved that the lead concentration in the ferroelectric layer decreases in a stepped manner with increasing distance from the first metal layer 3 by lowering only the sputter rate of the lead, in particular by lowering the electrical power applied on the sputter target that includes the lead. On the other hand, the electrical currents that are applied on the sputter target that includes the zirconium and the sputter target that includes the titanium remain unchanged. The electrical power applied on the sputter target that includes the lead is decreased starting from an electrical starting power P_{max,lead} by a value of 0.2 W to 2 W per a distance of 100 nm from the first metal layer 3, the value is in particular 1 W per a distance of 100 nm from the first metal layer 3. In order to form the oxides of the lead zirconate titanate, the atmosphere, in which the sputtering is performed, includes oxygen. In addition, the atmosphere can additionally include argon.

In FIG. 2 it is shown how the variation of the electrical power that is applied on the sputter target that includes the lead leads to a variation of the lead concentration in the ferroelectric layer 5. The ferroelectric layer 5 was thereby made with a thickness of 1200 nm, wherein every 400 nm the electrical power that is applied on the sputter target that includes the lead is decreased by 5 W. A plot is shown in FIG. 2, in which the electrical power that is applied on the sputter target that includes the lead is plotted over the horizontal axis and a ratio c(Pb)/c(O) is plotted over the vertical axis, wherein c(O) is the oxygen concentration in the ferroelectric layer 5. The electrical power P_{max,lead} is denoted with the reference number 9, the electrical power P_{max,lead}−5 W is denoted with the reference number 10, and the electrical power P_{max,lead}−10 W is denoted with the reference number 11. The ratio c(Pb)/c(O) was determined on the edge 7 of the substrate 1 and the center 8 of the substrate 1. It is clearly visible that the lead concentration decreases with decreasing electrical power. The decrease of the lead concentration is more pronounced in the center 8 than on the edge 7.

The table shown below shows a comparison of the pyroelectric coefficients of a first micromechanic structure with the uniform lead concentration that was obtained by the electrical power that was applied on the sputter target that includes the lead being P_{max,lead} during the complete sputtering with a second micromechanic structure that has a stepped decrease of the lead concentration in the ferroelectric layer 5, wherein the lead concentration was obtained according to FIG. 2. The pyroelectric coefficient was determined on eight different points, wherein “center” denotes the center 8 and “top” denotes the edge 7. The eight different points are arranged in a descending order in the table and correspond to a movement of the points from inside to outside on the substrate.

| | pyroelectric coefficient | pyroelectric coefficient |
|---|---|---|
| position on | * 10⁻⁴*C/m²K | * 10⁻⁴*C/m²K |
| substrate 1 | uniform lead concentration | stepped lead concentration |
| center | 1.05 | 2.1 |
| C-T 1 | 1.15 | 2.05 |
| C-T-2 | 1.29 | 2.12 |
| C-T-3 | 1.39 | 2.14 |
| C-T-4 | 1.56 | 2.13 |
| C-T-5 | 1.76 | 2.11 |
| C-T-6 | 1.83 | 2.09 |
| top | 2 | 2.11 |

It can be seen that with the uniform lead concentration the pyroelectric coefficient varies from 1.05*10⁻⁴*C/m²K in the center to 2.00*10⁻⁴*C/m²K on the edge of the micromechanic structure. On the other hand, it was unexpectedly found that with the stepped decrease of the lead concentration the variation of the pyroelectric coefficient is less than 5% of the maximum value of pyroelectric coefficient and is therefore substantially smaller then if the lead concentration would be uniform in the complete ferroelectric layer.

It is understood that the foregoing description is that of the exemplary embodiments of the disclosure and that various changes and modifications may be made thereto without departing from the spirit and scope of the disclosure as defined in the appended claims.

### LIST OF REFERENCE NUMERALS

1 substrate
2 carrier membrane
3 adhesion layer
4 first metal layer
5 ferroelectric layer
6 lead concentration characteristics
7 edge
8 center
9 P_{max,lead}
10 P_{max,lead}−5 W
11 P_{max,lead}−10 W
12 boundary layer
13 partial layer

What is claimed is:

1. A micromechanic structure comprising:
a substrate;
an adhesion layer arranged on the substrate;
a first metal layer arranged on the adhesion layer;
a ferroelectric layer arranged on the first metal layer and including lead zirconate titanate, a lead concentration of the ferroelectric layer decreasing in a stepped manner with an increasing distance from the first metal layer such that the ferroelectric layer includes a plurality of partial layers in which the lead concentration is respectively uniform; and
a second metal layer arranged on the ferroelectric layer.

2. The micromechanic structure according to claim 1, wherein a thickness of each of the plurality of partial layers is in a range from 100 nm to 900 nm.

3. The micromechanic structure according to claim 1, wherein a thickness of each of the plurality of partial layers is in a range from 400 nm to 600 nm.

4. The micromechanic structure according to claim 1, wherein a thickness of each of the plurality of partial layers is 500 nm.

5. The micromechanic structure according to claim 1, wherein a thickness of the ferroelectric layer is in a range from 200 nm to 5000 nm.

6. The micromechanic structure according to claim 1, wherein the ferroelectric layer has a pyroelectric coefficient higher than 1.5*10-4 C/(m²K).

7. The micromechanic structure according to claim 1, wherein:
in the ferroelectric layer
c(Pb)/(c(Zr)+c(Ti)) is in a range from 0.9 to 1.0,
c(Zr)/(c(Zr)+c(Ti)) is in the range from 0.1 to 0.3,
c(Pb) is the lead concentration,
c(Zr) is a zirconium concentration, and
c(Ti) is a titanium concentration.

8. The micromechanic structure according to claim 1, wherein the micromechanic structure is an infrared light sensor and/or an actuator.

9. A method for making the micromechanic structure, the method comprising:
providing the micromechanic structure according to claim 1; and
arranging the ferroelectric layer on the first metal layer by a sputter process.

10. The method according to claim 9, wherein the sputter process is a confocal sputter process.

11. The method according to claim 9, further comprising:
simultaneously depositing lead, zirconium, and titanium of the lead zirconate titanate from three different sputter targets, wherein each of the three different sputter targets includes only one of the lead, the zirconium, and the titanium.

12. The method according to claim 9, further comprising:
decreasing the lead concentration in the ferroelectric layer in the stepped manner with the increasing distance from the first metal layer by lowering only a sputter rate of the lead.

13. The method according to claim 9, further comprising:
decreasing the lead concentration in the ferroelectric layer in the stepped manner with the increasing distance from the first metal layer by lowering an electrical power applied on a sputter target that includes the lead.

14. The method according to claim 13, wherein the electrical power applied on the sputter target that includes the lead is lowered starting from an electrical start power P_{max,lead} by a value in a range from 0.2 W to 2 W per a distance of 100 nm from the first metal layer.

15. The method according to claim 13, wherein the electrical power applied on the sputter target that includes the lead is lowered starting from an electrical start power P_{max,lead} by a value of 1 W per a distance of 100 nm from the first metal layer.
